(19) United States
(12) Patent Application Publication
(10) Pub. No.: US 2010/0037948 A1
(43) Pub. Date: Feb. 18, 2010

(54) SOLAR CELLS PROVIDED WITH COLOR MODULATION AND METHOD FOR FABRICATING THE SAME

(75) Inventors: HUEY-LIANG HWANG, Hsinchu City (TW); CHENG-CHUNG LEE, Hsinchu City (TW); NAEJYE HWANG, Hsinchu City (TW); HSIANG-CHIH YANG, Hsinchu City (TW); MENG-HSUN SUNG, Hsinchu City (TW)

Correspondence Address: WPAT, PC;INTELLECTUAL PROPERTY ATTORNEYS, 7225 BEVERLY ST., ANNANDALE, VA, 22003, US

(73) Assignee: INTEGRATED DIGITAL TECHNOLOGIES, INC., Hsinchu City (TW)

(21) Appl. No.: 12/468,606

(22) Filed: May 19, 2009

Related U.S. Application Data
(60) Provisional application No. 61/088,779, filed on Aug. 14, 2008.

(51) Int. Cl. H01L 31/0232; H01L 31/18

(52) U.S. Cl. 136/256; 438/61; 257/E31.127

(57) ABSTRACT

Solar cells provided with color modulation and a method for fabricating the same are disclosed. The solar cell includes a photoelectric conversion layer and a color-modulating layer provided over the photoelectric conversion layer. The photoelectric conversion layer is employed for generating electrical energy from incident light and the color-modulating layer is used to modulate colorful appearance.

### BACKGROUND OF THE INVENTION

1. Field of the Invention

The present inventions relates to photovoltaic cells capable of converting solar radiation into usable electrical energy. More specifically, the present invention relates to solar cells provided with color modulation and a method for fabricating the same.

2. Description of the Related Art

Solar cells or photovoltaic cells are devices that convert light energy of sunlight into electrical energy by means of photoelectric conversion mechanism. From the view point of global environmental conservation, the solar cell is highly expected to generate electricity and actively developed for widespread commercialization in recent years. Buildings, vehicles and other objects may be covered in part with solar cells to maximize the use of solar energy. For decorative or aesthetic reasons, solar cell units may be required to have different colors. As an example, when the solar cells are employed to cover roofs or walls of buildings, different colors may be required for being integrated into the color(s) of the buildings or surrounding environment in consideration of design choice or aesthetic appearance.

Conventional approaches, such as U.S. Pat. Nos. 5,725,006 and 6,049,035, for providing solar cells with different colors may require additional manufacturing process or may deteriorate the photoelectric conversion efficiency of the solar cells. Therefore, it is desirable to provide solar cells with variable colors without complicated designs or processes or without too much impact on the solar power conversion efficiency thereof.

### SUMMARY OF THE INVENTION

One objective of the present invention is to provide solar cells provided with color modulation and a method for fabricating the same. The solar cell includes a photoelectric conversion layer and a color-modulating layer provided over the photoelectric conversion layer. The photoelectric conversion layer is employed for generating electrical energy from incident light and the color-modulating layer is used to modulate colorful appearance or enhance photoelectric conversion efficiency.

One embodiment of the present invention discloses solar cell comprising:
a photoelectric conversion layer for generating electrical energy from incident light;
at least one first electrode and at least one second electrode formed over the photoelectric conversion layer for outputting the electrical energy; and
a color-modulating layer provided over the photoelectric conversion layer to modulate colorful appearance thereof.

The solar cell in accordance with the present invention further comprises a passivation layer formed over the color-modulating layer and a transparent layer formed over the passivation layer.

Another embodiment of the present invention discloses a method for fabricating a solar cell comprising the steps of:
providing a photoelectric conversion layer;
forming at least one first electrode and at least one second electrode over the photoelectric conversion layer; and
forming a color-modulating layer over the photoelectric conversion layer to modulate colorful appearance or enhance photoelectric conversion efficiency thereof.

The method in accordance with the present invention further comprises the steps of forming a passivation layer over the color-modulating layer and forming a transparent layer over the passivation layer.

### BRIEF DESCRIPTION OF THE DRAWINGS

Other features and advantages of the present invention will be apparent from the detailed description of the invention that follows, taken in conjunction with the accompanying drawings of which:

FIGS. 1-5 schematically illustrate a process for fabricating solar cells in accordance with one preferred embodiment of the present invention in cross-sectional views of partial presentation;

FIG. 6 illustrates the reflective spectrum of a solar cell as exemplified in Example I;

FIG. 7 illustrates the refractive index vs. wavelength curve of a color-modulating layer in Example II;

FIG. 8 illustrates the reflective spectrum of a solar cell as exemplified in Example II;

FIG. 9 illustrates the refractive index vs. wavelength curve of a color-modulating layer in Example III;

FIG. 10 illustrates the reflective spectrum of a solar cell as exemplified in Example III; and

FIG. 11 illustrates the reflective spectrum of a solar cell as exemplified in Example IV.

### DETAILED DESCRIPTION OF PREFERRED EMBODIMENT

Certain terms are used through the description and following claims to refer to particular elements. As one skilled in the art will appreciate, solar cell manufacturers may refer to a element by different names. This document does not intend to distinguish between elements that differ in name but not function. In the following description and in the claims, the terms “include” and “comprise” are used in an open-ended fashion, and thus should be interpreted to mean “include, but not limited to . . . ” Also, the term “formed on” or formed over” are intended to mean either indirect or direct contact between two layers. Accordingly, if an upper layer is “formed on” or “formed over” a lower layer, two layers may be direct contact with each other, or an intermediate layer may be inserted or deposed between the two layers.

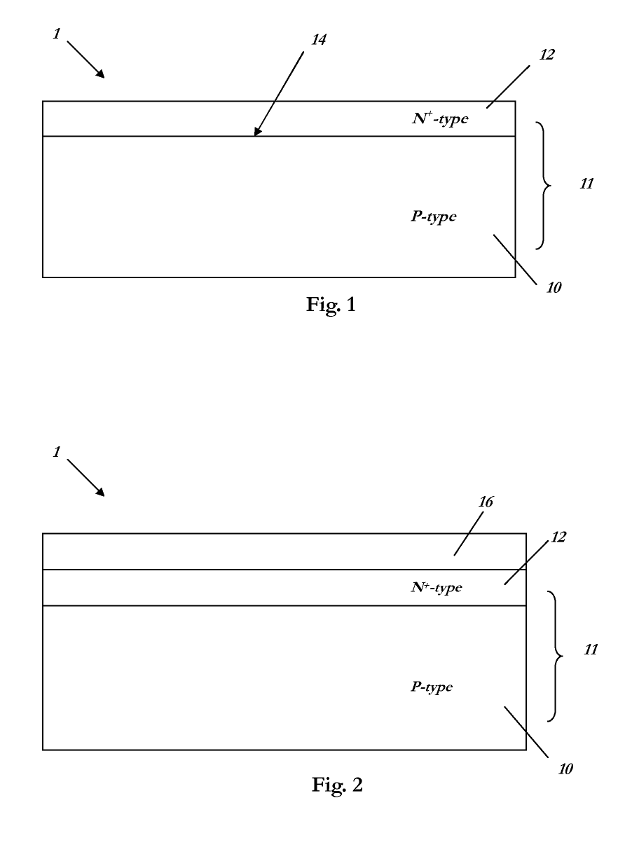

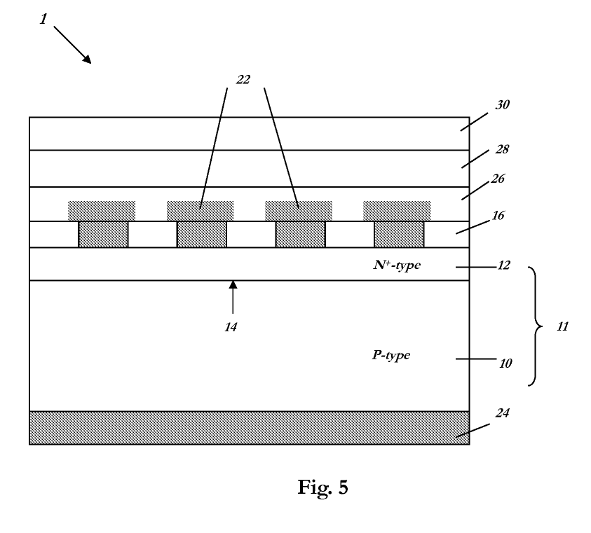

FIGS. 1 through 5 schematically illustrates the process flow for fabricating a solar cell unit 1 according to one preferred embodiment of the present invention in cross-sectional views of partial representation. Referring to FIG. 1, an n-type semiconductor layer 12 is formed on a p-type semiconductor substrate 10 so as to form a p-n junction 14 therebetween. As such, an electric field can be established at the p-n junction 14. Light striking on this electric field may separate the positive charge carriers and the negative charge carriers, thus creating an electrical current passing through the p-n junction 14, which is so-called photoelectric conversion mechanism. Generally speaking, the combination of the p-type semiconductor substrate 10 and the n-type semiconductor layer 12 constitutes a photoelectric conversion layer 11 which is employed to generate electrical energy from incident light. The p-type semiconductor substrate 10 may be a p-type silicon substrate such that the n-type semiconductor layer 12 can be conformably deposited over the p-type semiconductor substrate 10 or formed by means of doping n-type impurities into the p-type semiconductor substrate 10. Alternately, an n-type semiconductor substrate in combination of a p-type semiconductor layer can be utilized to constitute the photoelectric conversion layer 11 as well. Generally speaking, the photoelectric conversion layer 11 may be made of one or more semiconductor materials, such as single crystalline, polycrystalline, amorphous state of semiconductor material such as silicon, germanium or the like.

As shown in FIG. 2, the transparent anti-reflection layer 16 is formed over the photoelectric conversion layer 11 and may be made of silicon nitride by means of an evaporation method, a sputtering method, a print screen method, a CVD method or any other methods that are known to the persons skilled in the art. The anti-reflection layer 16 is employed to protect the solar cell unit 1 and also decreases reflective loss on the unit surface. Preferably, the anti-reflection layer 16 has a thickness ranging from 1 nm to 500 nm.

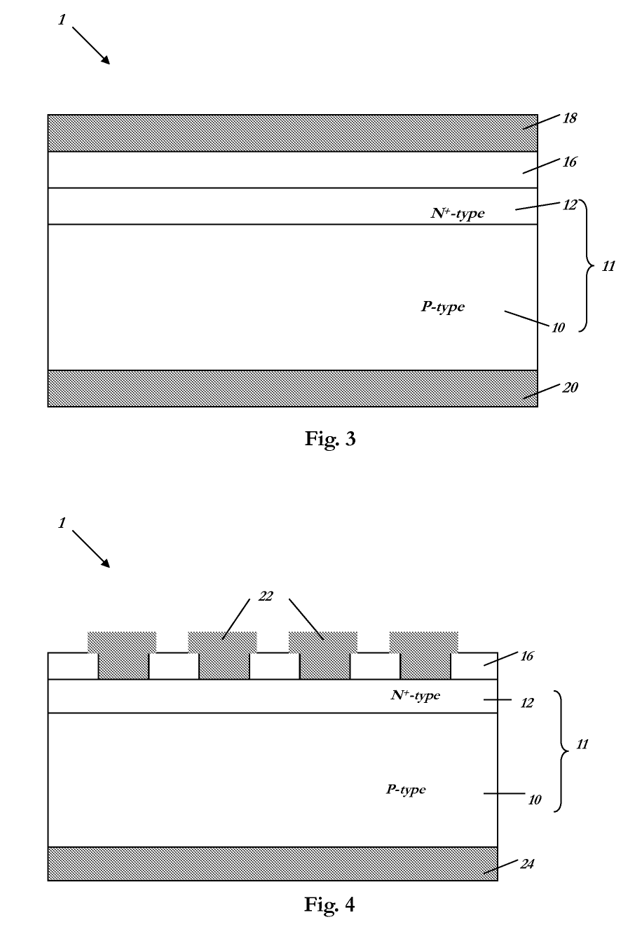

Conductive layers 18 and 20 are thereafter formed over opposite surfaces of the photoelectric conversion layer 11 by an evaporation method, a sputtering method, a print screen method, a CVD method or any other methods that are known to the persons skilled in the art. As shown in FIG. 3, the conductive layer 18 is formed over the front surface of the photoelectric conversion layer 11 and, therefore, on the anti-reflection layer 16. The conductive layer 20 is formed over the back surface of the photoelectric conversion layer 11 in contact with the p-type substrate 10. The conductive layer 18 or 20 may be made of metal or alloy, for example, gold, silver, aluminum, copper, or platinum or the like, and could be made of transparent conductive oxide (TCO) layer such as ITO film or a ZnO film as well.

The conductive layer 18 can be subject to heat treatment such that conductive material contained in the conductive layer 18 can pass through the anti-reflection layer 16 to be in contact with the n-type semiconductor layer 12 by means of spiking effect. In addition, the conductive layers 18 and 20 can be patterned into parallel lines to form front electrodes 22 and back electrodes 24 respectively. As shown in FIG. 4, the front electrodes 22 are electrically connected with the n-type semiconductor layer 12 and the back electrodes 24 are electrically connected to the p-type semiconductor substrate 10. Accordingly, the front electrodes 22 and the back electrodes 24 are formed to become two electrical terminals for the photoelectric conversion layer 11. In other words, the electrodes 22 and 24 are used to charge or discharge the electrical energy generated from the photoelectric conversion layer 11 if the solar cell unit 1 is subject to light of sunlight. Preferably, the back electrodes 24 may be formed into various shapes or structures, such as a concavo-convex structure, to facilitate light collection. Moreover, the front electrodes 22 may be formed so as to have a surface-textured structure including a rough surface structure, or so-called textured pattern. When the surface of the electrodes 22 are provided with such a textured pattern, the incidence efficiency of light into the photoelectric conversion layer 11 can be improved.

According to the present invention, the color-modulating layer 26 is formed over the anti-reflection layer 16 so as to provide the solar cell unit 1 with variable colors. The color-modulating layer 26 may be composed of one or more dielectric material over the anti-reflection layer 16 under a vacuum or near-vacuum environment by a coating method, an evaporation method (such as e-gun), a sputtering method, a CVD method or other methods if suitable and feasible.

Various dielectric materials or combination of thereof may be utilized. In some examples, materials such as oxides (SnO₂, Al₂O₃, SiO, ZnO, Y₂O₃, Ta₂O₅, TiO₂, Cr₂O₃, etc.), fluorides (MgF₂, Na₃AlF₆, etc.), sulphides (ZnS, PbS, CdS, etc.), nitrides (Si₃N₄, AlN, AlOₓN_{y}, etc.), tellurides (CdTe, etc.) and selenides (PbSe), and/or the like. In various examples, the thickness of the color-modulating layer 26 may range from 1 nm or less to 5000 nm depending on various applications.

By providing color-modulating layer 26 over the anti-reflection layer 16, desirable visual effect may be achieved without suffering from conversion efficiency loss and using complicated manufacturing methods. In some examples, the color-modulating layer 26 can decrease reflective loss so as to enhance solar power conversion efficiency.

Thereafter, a passivation layer 28 and a transparent layer 30 are sequentially formed to cover the color-modulating layer 26. The passivation layer 28 is a transparent film made of, preferably, ethylene vinyl acetate (EVA) or polyvinyl butyral (PVB) in order to prevent the solar cell unit from direct exposure to sun and rain or subject to humidity. The transparent layer 30 is preferably made of treated or nontreated glass.

It is noted that the step sequence of the aforementioned embodiment can be modified in consideration of practical use. For example, the formation of the electrodes 22 and 24 can be performed behind the formation of the color-modulating layer 26. Therefore, the exemplified embodiment cannot be used to interpret the scope of claims in limiting sense.

There are some examples are provided for reference as follows.

### Example I

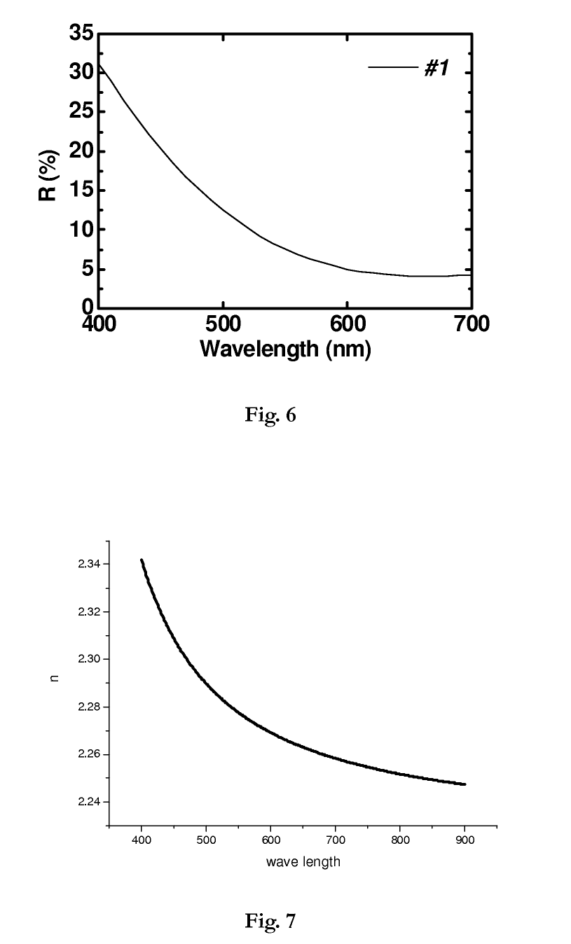

The photoelectric conversion layer 11 is made of a silicon layer of a first conductivity type formed in/on a silicon substrate of a second conductivity type. If the first conductivity type is p-type, the second conductivity type is n-type. To the contrary, the second conductivity type is p-type if the first conductivity type is n-type. As an example, the photoelectric conversion layer 11 is formed of silicon has a refractive index (n) in the range of 3.4˜3.6 and has thickness in the range of 140˜250 μm. The anti-reflective layer 16 is formed of silicon nitride having a refractive index (n) in the range of 1.8˜2.2 and a thickness in the range of 60˜120 nm. It is noted that no color-modulating layer 26 is formed to overlie the underlying layers to be compared with Examples II, III and IV. Accordingly, the reflective spectrum thereof is measured and illustrated in FIG. 6. The CIE Lk*a*b* values thereof are measured to be 34.92, 1.73 and −29.49, respectively.

### Example II

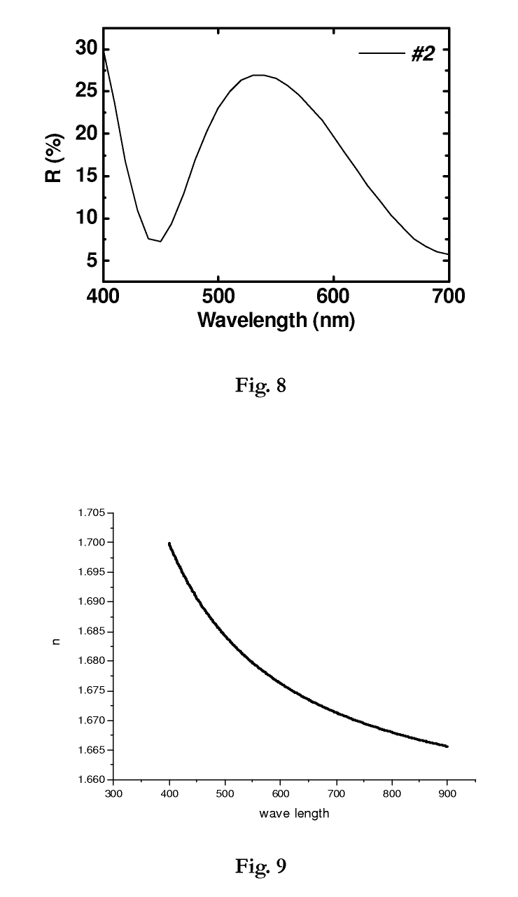

The photoelectric conversion layer 11 is made of a silicon layer of a first conductivity type formed in/on a silicon substrate of a second conductivity type. If the first conductivity type is p-type, the second conductivity type is n-type. To the contrary, the second conductivity type is p-type if the first conductivity type is n-type. As an example, the photoelectric conversion layer 11 is formed of silicon has a refractive index (n) in the range of 3.4˜3.6 and has thickness in the range of 140˜250 μm. The anti-reflective layer 16 is formed of silicon nitride having a refractive index (n) in the range of 1.8˜2.2 and a thickness in the range of 60˜120 nm. The color-modulating layer 26 is made of a material having a thickness of about 1,600˜2,000 Å and a refractive index vs. wavelength curve as shown in FIG. 7. As such, the reflective spectrum thereof is measured and illustrated in FIG. 8. The CIE Lk*a*bA* values are measured to be 56.65, −18.54 and 23.76, respectively.

### Examples III

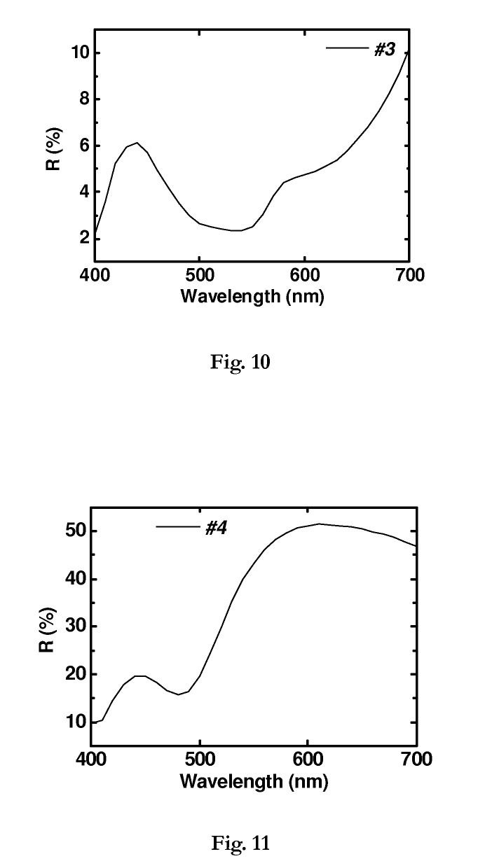

The photoelectric conversion layer 11 is made of a silicon layer of a first conductivity type formed in/on a silicon substrate of a second conductivity type. If the first conductivity type is p-type, the second conductivity type is n-type. To the contrary, the second conductivity type is p-type if the first conductivity type is n-type. As an example, the photoelectric conversion layer 11 is formed of silicon has a refractive index (n) in the range of 3.4˜3.6 and has thickness in the range of 140˜250 μm. The anti-reflective layer 16 is formed of silicon nitride having a refractive index (n) in the range of 1.8˜2.2 and a thickness in the range of 60˜120 nm. The color-modulating layer 26 is made of a material having a thickness of about 800˜1,200 Å and a refractive index vs. wavelength curve as shown in FIG. 9. As such, the reflective spectrum thereof is measured and illustrated in FIG. 10. The CIE Lk*a*bA* values are measured to be 22, 14.41 and −8.29, respectively.

### Examples IV

The photoelectric conversion layer 11 is made of a silicon layer of a first conductivity type formed in/on a silicon substrate of a second conductivity type. If the first conductivity type is p-type, the second conductivity type is n-type. To the contrary, the second conductivity type is p-type if the first conductivity type is n-type. As an example, the photoelectric conversion layer 11 is formed of silicon has a refractive index (n) in the range of 3.4˜3.6 and has thickness in the range of 140˜250 μm. The anti-reflective layer 16 is formed of silicon nitride having a refractive index (n) in the range of 1.8˜2.2 and a thickness in the range of 60˜120 nm. The color-modulating layer 26 is composed of multiple layers; that is, three layers are provided in this example. In the example, a first layer is provided with a refractive index (n1) in the range of 2.15˜2.55 and a thickness in the range of 750˜1100 Å; a second layer is provided with a refractive index (n2) in the range of 3.6˜4.0 and a thickness in the range of 1,550˜1,950 Å; a third layer is provided with a refractive index (n3) on the range of 2.15˜2.55 and a thickness in the range of 960˜1360 Å. The first, second and third layers are stacked sequentially from bottom to top. Therefore, the reflective spectrum thereof is measured and illustrated in FIG. 11. The CIE Lk*a*b* values are measured to be 47.05, 28.63 and −13.77, respectively.

The examples given hereinbefore show that the present invention provides those skilled in the art with the means to design solar cells with color-modulating layer having the most simple structure possible and sufficient efficiency, while exhibiting a predetermined color, so that they are well suited to serve as building material or whatever aesthetic appearance of which is an important requirement.

Although the invention has been described above by the embodiment and the examples, the invention is not limited to the foregoing embodiments and examples but can be variously modified. The material of the color modulation is not always limited to any of the materials in the lists but can be freely sets as long as the external color of the solar cell can be adjusted by using color modulation property of the color colulating layer 26. More specifically, the material of the color modulating layer 26 may be, for example, oxides, fluorides, sulphides, nitrides, tellurides and selenides of a kind other than the kinds listed above, or a material other than oxides, fluorides, sulphides, nitrides, tellurides and selenides.

Obviously, many modifications and variations of the present invention are possible in the light of the above teachings. It is therefore to be understood that within the scope of appended claims, the invention may be practiced otherwise than as specifically described.

What is claimed is:

1. A solar cell comprising:
a photoelectric conversion layer for generating electrical energy from incident light;
at least one first electrode and at least one second electrode formed over the photoelectric conversion layer for outputting the electrical energy; and
a color-modulating layer provided over the photoelectric conversion layer to modulate colorful appearance thereof.

2. The solar cell as claimed in claim 1, further comprising an anti-reflection layer laminated between the color-modulating layer and the photoelectric conversion layer.

3. The solar cell as claimed in claim 2, wherein the at least one first electrode is provided in contact with the photoelectric conversion layer through the anti-reflection layer.

4. The solar cell as claimed in claim 1, wherein the color-modulating layer included comprises at least one of oxides, fluorides, sulphides, nitrides, tellurides and selenides.

5. The solar cell as claimed in claim 1, wherein the color-modulating layer is composed of a plurality of films.

6. The solar cell as claimed in claim 1, wherein the color-modulating layer has a thickness in the range of about 1 nm to 5000 nm.

7. The solar cell as claimed in claim 1, wherein the photoelectric conversion layer has a textured surface.

8. The solar cell as claimed in claim 1, wherein the photoelectric conversion layer has a non-textured surface.

9. The solar cell as claimed in claim 1, further comprising a passivation layer and a transparent layer sequentially formed over the color-modulating layer.

10. The solar cell as claimed in claim 9, wherein the passivation layer has a refractive index in the range of 1.4˜1.6

11. The solar cell as claimed in claim 10, wherein the passivation layer is made of at least one of ethylene vinyl acetate (EVA) and polyvinyl butyral (PVB).

12. The solar cell as claimed in claim 9, wherein the transparent layer has a refractive index in the range of 1.4˜1.6.

13. The solar cell of claim 12, wherein the transparent layer is made of glass.

14. The solar cell as claimed in claim 1, wherein the first electrode and the second electrode are formed over the same surface of the photoelectric conversion layer.

15. The solar cell as claimed in claim 1, wherein the first electrode and the second electrode layer are formed over the opposite surfaces of the photoelectric conversion layer.

16. A method of fabricating a solar cell, the method comprising:
providing a photoelectric conversion layer;
forming at least one first electrode and at least one second electrode over the photoelectric conversion layer; and
forming a color-modulating layer over the photoelectric conversion layer to modulate colorful appearance thereof.

17. The method as claimed in claim 16, further comprising a step of forming an anti-reflection layer laminated between the color-modulating layer and the photoelectric conversion layer.

18. The method as claimed in claim 17, further comprising a step of forming the at least one first electrode in contact with the photoelectric conversion layer through the anti-reflection layer.

19. The method as claimed in claim 16, wherein the color-modulating layer includes comprises at least one of oxides, fluorides, sulphides, nitrides, tellurides and selenides.

20. The method as claimed in claim 16, wherein the color-modulating layer has a thickness in the range of about 1 nm to 5000 nm.

21. The method as claimed in claim 16, wherein the step of forming the color-modulating layer is performed under a vacuum or near vacuum environment.

22. The method as claimed in claim 16, wherein the photoelectric conversion layer has a textured surface.

23. The method as claimed in claim 16, wherein the photoelectric conversion layer has a non-textured surface.

24. The method as claimed in claim 16, further comprising:
forming a passivation layer over the color-modulating layer; and
forming a transparent layer over the passivation layer.

25. The method as claimed in claim 24, wherein the passivation layer has a refractive index in the range of 1.4˜1.6.

26. The method as claimed in claim 25, wherein the passivation layer is made of at least one of ethylene vinyl acetate (EVA) and polyvinyl butyral (PVB).

27. The method as claimed in claim 24, wherein the transparent layer has a refractive index in the range of 1.4˜1.6.

28. The method as claimed in claim 27, wherein the transparent layer is made of glass.

29. The method as claimed in claim 16, wherein the first electrode and the second electrode are formed over the same surface of the photoelectric conversion layer.

30. The method as claimed in claim 16, wherein the first electrode and the second electrode are formed over the opposite surfaces the photoelectric conversion layer.
